(19) United States
(12) Patent Application Publication
(10) Pub. No.: US 2011/0001222 A1
(43) Pub. Date: Jan. 6, 2011

(54) ELECTRONIC DEVICE, LAYERED SUBSTRATE, AND METHODS OF MANUFACTURING SAME

(76) Inventors: Nozomu Nishimura, Tokyo (JP); Toshinobu Ogatsu, Tokyo (JP); Katsumi Abe, Tokyo (JP)

Correspondence Address: Mr. Jackson Chen, 6535 N. STATE HWY 161, IRVING, TX, 75039, US

(21) Appl. No.: 12/865,202

(22) PCT Filed: Feb. 17, 2009
(86) PCT No.: PCT/JP2009/052687

§ 371 Date: Jul. 29, 2010

(30) Foreign Application Priority Data
Feb. 18, 2008 (JP) 2008-036084
Jun. 30, 2008 (JP) 2008-170908

(51) Int. Cl. H01L 23/552; H01L 23/48; H01L 21/60

(52) U.S. Cl. 257/660; 257/774; 438/118; 257/E23.011; 257/E21.514; 257/E23.114

(57) ABSTRACT

An electronic device comprises an electronic element package and a mounting substrate on which the electronic element package is mounted. The electronic element package has an LGA electrode. The mounting substrate has a through-hole having a conductor which covers an inner wall. The LGA electrode has an area larger than an opening area of the through-hole on a side facing the LGA electrode. The electronic element package is mounted on the mounting substrate so that at least a part of the opening of the through-hole overlaps with the LGA electrode. The LGA electrode and the conductor of the through-hole are electrically connected to a conductive material provided inside the through-hole. In the LGA electrode, at least a part of the region that does not overlap with the opening of the through-hole is joined to the mounting substrate by an adhesive.

### REFERENCE TO RELATED APPLICATION

This application is the National Phase of PCT/JP2009/052687, filed Feb. 17, 2009, which claims the benefits of Japanese Patent Applications No. 2008-036084, filed Feb. 18, 2008, and No. 2008-170908, filed Jun. 30, 2008, which are hereby incorporated by reference herein in their entireties.

### TECHNICAL FIELD

The present invention relates to an electronic device in which an electronic element package is mounted on a mounting substrate and a manufacturing method thereof and, in particular, an electronic device in which an electronic element package having an electrode of an LGA (Land Grid Array) type is mounted on a mounting substrate and a manufacturing method thereof. The present invention also relates to a layered substrate in which a plurality of mounting substrates are layered and a manufacturing method thereof.

### BACKGROUND

With a demand for downsizing/slimming and high-integrating a personal computer and mobile communication apparatus of recent years, downsizing/slimming and high-integrating an electronic device (a semiconductor device, for example) which is installed therein is in great demand. With this a mainstream of an electronic element package (a semiconductor element package, for example) is shifting from a QFP (Quad Flat Package) in which connection terminals are disposed around a package to a package, referred as a BGA (Ball Grid Array), which can realize multi-terminal connection even in a smaller area by arranging solder balls, which are connection terminals, in a grid form on a interposer substrate that is on a back face of the package.

In the mounting of the BGA, cream solder in a paste form is printed to an electrode of a mounting substrate using a metal mask, and then the BGA is mounted. After this, the BGA and the mounting substrate are physically and electrically connected by passing the mounting substrate on which the BGA is mounted through a reflow furnace to heat and melt the cream solder and solder ball of the BGA.

Alternative to the BGA, an LGA (Land Grid Array) which has a planar electrode arranged in a grid form as a connection terminal is also known as an electronic element package having no solder ball. The LGA can have lower mounting height than the BGA by height corresponding to the solder ball.

Mounting methods of the BGA are disclosed in Patent Document 1 and Patent Document 2, for example.

In a mounting method of the BGA described in Patent Document 1, thermosetting adhesive that sets at a temperature higher than the melting point of the solder is applied at a predetermined position between pads of a printed board which is on through-holes of the printed board; then the solder ball connected with the pad of the BGA is put and mounted on the through-hole of the printed board; the solder ball flows into the through-hole upon heating the BGA and the printed board; and the pad of the BGA and the pad of the printed board are joined with the solder and a body of the BGA and the substrate of the printed board are joined with an adhesive.

In a method of manufacturing a layered-component-built-in flexible circuit board described in Patent Document 2, an active element of a BGA type is mounted by forming a wiring layer formed of a conductor having an electrode portion on an insulating substrate of a sheet form, providing a via hole or through-hole at a predetermined position of a part of the wiring layer and of the electrode portion, putting one or more passive elements or active elements connected to the wiring layer; forming the insulating substrate of a sheet form in a component-built-in flexible circuit board by filling the inside of the via hole or through-hole with the solder, and laminating a plurality of the component-built-in flexible circuit boards through a gap-filling insulating sheet, to form a solid body.

In order to obtain a semiconductor device having an adequate strength even if a package is thin, in a semiconductor device described in Patent Document 3, a plurality of wiring films are formed on one surface; a reinforcing ring is fixed on the wiring film; a semiconductor chip is face-bonded in a region surrounding by the reinforcing ring in a state that each electrode is connected with a inner part of the corresponding wiring film.

[Patent Document 1] Japanese Patent Kokai Publication No. P2001-168511A
[Patent Document 2] Japanese Patent Kokai Publication No. P2005-45111A
[Patent Document 3] Japanese Patent Kokai Publication No. P2003-142634A

### SUMMARY

The entire disclosures of Patent Documents 1 to 3 are incorporated herein by reference thereto. The following analysis is given from a viewpoint of the present invention.

In the mounting of the BGA as described in Patent Document 1 and Patent Document 2, since a solder ball and cream solder of a mounting substrate are molten to be connected, there is a problem that a connection part of the BGA and the mounting substrate becomes thick. In a mobile communication apparatus and the like which are intensely required to be made thin in recent years, a BGA of a thin type (CSP (Chip Size Package), for example) having a thickness of about 0.5 mm is often used. However, since the thickness of the solder, which is formed by melting the solder ball and cream solder, to connect the BGA and the mounting board is about 0.25 mm, as a result, the mounting height of the BGA after the BGA is mounted on the mounting substrate becomes about 0.75 mm in spite of using the BGA of the thin type, and this becomes a problem in realizing the slim mobile communication apparatus.

In the mounting method of the BGA described in Patent Document 1, although there is an effect of improving reliability by applying the adhesive on the printed board, the adhesive spreads to the through-hole by heating in the reflow process and there is a possibility that the solder connection is prevented. In the mounting method described in Patent Document 1, although the thermosetting adhesive that begins to set at higher temperature than the melting point of the solder, there is a possibility that no contact between the solder ball and the printed board causes bad connection when heating causes a warp of the printed board and BGA.

In the method of manufacturing the layered-component-built-in flexible circuit board described in Patent Document 2, there is also a possibility that no contact between the electrode portion of the insulating substrate of the sheet form and the electrode of the active element causes defective connection when heating causes a warp of the printed board and/or the BGA.

In the semiconductor device described in Patent Document 3, since an ordinal bump connection is used in the electrical connection between the semiconductor chip and the wiring film, the semiconductor device is not be made thin as a whole.

It is an object of the present invention to provide an electronic device that is slim and has high connection reliability, in which an electronic element package of an LGA type is mounted, and a manufacturing method thereof. It is an object of the present invention to provide a layered substrate that is slim and has high connection reliability, in which a plurality of mounting substrates are layered and mounted, and a manufacturing method thereof.

According to a first aspect of the present invention, there is provided an electronic device in which an electronic element package is mounted on a first mounting substrate. The electronic element package has an LGA electrode of a Land Grid Array type. The first mounting substrate has a through-hole having a conductor which covers an inner wall. The electronic element package is mounted on the first mounting substrate so that at least a part of an opening of the through-hole overlaps with the LGA electrode. The LGA electrode and the conductor of the through-hole are electrically connected by a conductive material provided inside the through-hole. In the LGA electrode, at least a part of a region that does not overlap with the opening of the through-hole is joined with the first mounting substrate by an adhesive.

According to a preferred mode of the first aspect, the electronic device further comprises a second mounting substrate having a substrate electrode electrically connected with the conductor of the through-hole. The first mounting substrate is mounted on the second mounting substrate so that at least a part of the opening of the through-hole overlaps with the substrate electrode. The substrate electrode and the conductor of the through-hole are electrically connected by a conductive material provided inside the through-hole. In the substrate electrode, at least a part of a region that does not overlap with the opening of the through-hole is joined with the first mounting substrate by an adhesive.

According to a preferred mode of the first aspect, an area of the LGA electrode or an area of the LGA electrode and the substrate electrode is larger than an opening area of the through-hole on a side facing to the LGA or the LGA and the substrate electrode.

According to a second aspect of the present invention, there is provided an electronic device in which an electronic element package is mounted on a first mounting substrate. The electronic element package has an LGA electrode of a Land Grid Array type. The first mounting substrate has a through-hole having a conductor which covers an inner wall. The LGA electrode has an area smaller than an opening area of the through-hole on a side facing to the LGA electrode. The electronic element package is mounted on the first mounting substrate so that the LGA electrode is included in an opening of the through-hole. The LGA electrode and the conductor of the through-hole are electrically connected by a conductive material provided inside the through-hole. An upper surface of the LGA electrode facing to the first mounting substrate is located inside the through-hole. An adhesive is provided, on an area in which the electronic element package faces the first mounting substrate, in a region other than a region of the opening of the through-hole.

According to a preferred mode of the second aspect and second aspect, the electronic device further comprises a second mounting substrate having a substrate electrode electrically connected in the conductor of the through-hole. The substrate electrode has an area smaller than an opening area of the through-hole on a side facing the substrate electrode. The first mounting substrate is mounted on the second mounting substrate so that the substrate electrode is included in an opening of the through-hole. The substrate electrode and the conductor of the through-hole are electrically connected by the conductive material provided inside the through-hole. An upper surface of the substrate electrode facing to the first mounting substrate is located inside the through-hole. In an area in which the first mounting substrate faces the second mounting substrate, an adhesive is provided in a region other than a region of the opening of the through-hole.

According to a preferred mode of the first aspect and second aspect, the LGA electrode of the electronic element package is provided on a same plane with the substrate electrode of the second mounting substrate.

According to a preferred mode of the first aspect and second aspect, the second mounting substrate has a penetrating opening or notch. The electronic element package is disposed in the penetrating opening or notch.

According to a preferred mode of the first aspect and second aspect, the electronic element package is joined to the second mounting substrate with a resin.

According to a preferred mode of the first aspect and second aspect, at least one electronic element is mounted on the second mounting substrate.

According to a preferred mode of the second aspect, the LGA electrode or the LGA electrode and the substrate electrode is/are covered with the conductive material.

According to a preferred mode of the first aspect and second aspect, the first mounting substrate has a conductor that faces the LGA electrode or the LGA electrode and the substrate electrode, the conductor being successively formed with the conductor of the through-hole on a surface of the first mounting substrate facing to the electronic element package or the electronic element package and second mounting substrate. At least a part of a region that does not overlap with the opening of the through-hole in the LGA electrode or the LGA electrode and the substrate electrode is joined to the conductor on the surface of the first mounting substrate by an adhesive.

According to a preferred mode of the first aspect and second aspect, the first mounting substrate does not have a conductor that faces the LGA electrode or the LGA electrode and the substrate electrode, the conductor being successively formed with a conductor of the through-hole on a surface of the first mounting substrate facing to the electronic element package or the electronic element package and second mounting substrate.

According to a preferred mode of the first aspect and second aspect, in an area in which the first mounting substrate faces the electronic element package or the electronic element package and the second mounting substrate, an adhesive is provided on a region other than a region of the opening of the through-hole.

According to a preferred mode of the first aspect and second aspect, the adhesive is photosensitive resin.

According to a preferred mode of the first aspect and second aspect, in a region other than the through-hole, the first mounting substrate does not have optical transparency with respect to the electronic element package or the electronic element package and second mounting substrate.

According to a preferred mode of the first aspect and second aspect, the first mounting substrate has an opaque layer that shields light incident to the electronic element package or the electronic element package and the second mounting substrate in at least one part.

According to a preferred mode of the first aspect and second aspect, the conductive material is successively formed extending from the through-hole to a surface of the first mounting substrate on an opposite side of a surface of the first mounting substrate facing to the electronic element package or the electronic element package and the second mounting substrate.

According to a third aspect of the present invention, there is provided a layered substrate comprising a first mounting substrate and a second mounting substrate that is layered and mounted on the first mounting substrate. The second mounting substrate has a planar electrode. The first mounting substrate has a through-hole having a conductor that covers an inner wall. The first mounting substrate is mounted on a second mounting substrate so that at least a part of an opening of the through-hole overlaps with the planar electrode. The planar electrode and the conductor of the through-hole are electrically connected by a conductive material provided inside the through-hole. In the planar electrode, at least a part of a region that does not overlap with the opening of the through-hole is joined to the first mounting substrate with an adhesive.

According to a forth aspect of the present invention, a layered substrate comprising a first mounting substrate and a second mounting substrate that is layered and mounted on the first mounting substrate is provided. The second mounting substrate has a planar electrode. The first mounting substrate has a through-hole having a conductor that covers an inner wall. The planar electrode has an area smaller than an opening area of the through-hole on a side facing the planar electrode. The first mounting substrate is mounted on the second mounting substrate so that the planar electrode is included in the opening of the through-hole. The planar electrode and the conductor of the through-hole are electrically connected by a conductive material provided inside the through-hole. An upper surface of the planar electrode facing to the first mounting substrate is located inside the through-hole. In an area in which the first mounting substrate faces the second mounting substrate, an adhesive is provided in a region other than a region of the opening of the through-hole.

According to a preferred mode of the third aspect and fourth aspect, the adhesive is a photosensitive resin. In a region other than the through-hole, the first mounting substrate does not have optical transparency with respect to the second mounting substrate.

According to a fifth aspect of the present invention, there is provided a method of manufacturing an electronic device in which an electronic element package is mounted on a first mounting substrate, the method comprising: applying an adhesive on at least a part of a surface of the electronic element package in which an LGA electrode of a Land Grid Array type is formed; layering the electronic element package on the first mounting substrate having a through-hole that has a conductor on an inner wall so that at least a part of an opening of the through-hole overlaps with the LGA electrode; removing the adhesive in the through-hole so as to expose at least a part of the LGA electrode from the opening of the through-hole; supplying a conductive material to the through-hole from an opening on the opposite side of the opening of the through-hole facing the LGA electrode; and moving the conductive material the exposed surface of the LGA electrode, and electrically connecting the LGA electrode with the conductor of the through-hole by the conductive material.

According to a sixth aspect of the present invention, there is provided a method of manufacturing an electronic device. The method comprising: determining positions by gluing an electronic element package having an LGA electrode of a Land Grid Array type and a second mounting substrate on which at least one electronic element is mounted and has a planar electrode on an adhesive plate so that the LGA electrode and the planar electrode face the adhesive plate; joining the electronic element package and the second mounting substrate with a resin (first joining step); removing the electronic element package and the second mounting substrate from the adhesive plate; providing an adhesive on at least a part of a surface of the electronic element package on which the LGA electrode is formed and of a surface of the second mounting substrate on which the planar electrode is formed; layering a first mounting substrate that has at least one through-hole having a conductor on an inner wall on the electronic element package and the second mounting substrate so that at least a part of an opening of the through-hole overlaps with the LGA electrode and the planar electrode (second joining step); removing the adhesive in the through-hole so that at least a part of the LGA electrode and the planar electrode is exposed from the opening of the through-hole; supplying a conductive material to the through-hole from an opening on an opposite side of the opening of the through-hole facing the LGA electrode and the planar electrode; moving the conductive material to the exposed surface of the LGA electrode; and electrically connecting the planar electrode, and to connect the LGA electrode and the planar electrode with the conductor of the through-hole by the conductive material.

According to a preferred mode of the fifth aspect and sixth aspect, the LGA electrode or the LGA electrode and planar electrode has/have an area(s) larger than an opening area of the through-hole on a side facing the LGA electrode or the LGA electrode and planar electrode. In the second joining step, at least a part of a region that does not overlap with the opening of the through-hole in the LGA electrode or the LGA electrode and planar electrode is joined to the first mounting substrate by the adhesive.

According to a preferred mode of the fifth aspect and sixth aspect, the LGA electrode or the LGA electrode and planar electrode has/have an area(s) smaller than an opening area of the through-hole on a side facing the LGA electrode or the LGA electrode and planar electrode. In the second joining step, at least a part of the LGA electrode or of the LGA electrode and planar electrode, facing the first mounting substrate, is inserted into the through-hole.

According to a preferred mode of the third aspect, the adhesive is a photosensitive resin. The method comprises exposing the adhesive in the through-hole and removing the adhesive in the through-hole by a developing solution after the exposing the adhesive.

According to a preferred mode of the fifth aspect and sixth aspect, in a region other than the through-hole, the first mounting substrate has opacity with respect to the electronic element package or the electronic element package and the second mounting substrate. In the exposing, only the adhesive in the through-hole is exposed from the opening of the through-hole using the first mounting substrate as a mask.

According to a preferred mode of the fifth aspect and sixth aspect, the conductive material is cream solder. In the electrical connecting, the LGA electrode or the LGA electrode and planar electrode is/are electrically connected to the conductor of the through-hole by heating and melting the conductive material.

According to a seventh aspect of the present invention, there is provided a method of manufacturing a layered substrate. The method comprising: providing an adhesive at least on a part of a second mounting substrate in which a planar electrode is formed; layering a first mounting substrate that has a through-hole having a conductor on an inner wall on the second mounting substrate so that at least a part of an opening of the through-hole overlaps with the planar electrode; removing the adhesive in the through-hole so that at least a part of the planar electrode is exposed from the opening of the through-hole; supplying a conductive material to the through-hole from an opening on an opposite side of the opening of the through-hole facing the planar electrode; moving the conductive material to the exposed surface of the planar electrode; connecting the planar electrode to the conductor of the through-hole by the conductive material.

The present invention possesses at least one among the following effects.

According to the present invention, it is unnecessary to provide a conductive material between an LGA electrode of an electronic element package and second substrate electrode of a second mounting substrate and a first substrate electrode of a first mounting substrate, a distance between the electronic element package and second mounting substrate and the first mounting substrate can be shortened, and therefore an electronic device can be made slim. The electronic device can be further made slimmer by making areas of the LGA electrode and second substrate electrode smaller than an opening area of a through-hole, or not forming a first electrode (land) of the first mounting substrate.

If the areas of the LGA electrode and second substrate electrode are made smaller than the opening area of the through-hole, since a conductive material covers the LGA electrode and second substrate electrode, breakage is hard to occur at the connection part between the conductive material and the LGA electrode even if impact and the like are applied from the outside, and therefore connection reliability can be enhanced.

According to the present invention, since the electronic element package and second mounting substrate is joined to the first mounting substrate with an adhesive before electrical connection by the conductive material, a warp of the first mounting substrate caused by heat treatment can be restrained. Therefore, the reliability of the electrical connection between the electronic element package and second mounting substrate and the first mounting substrate can be enhanced.

According to the present invention, since only the adhesive existing inside the through-hole is removed, and a region except for the opening of the through-hole (including the periphery of the opening of the through-hole, for example) is joined with the adhesive, the reliability of the connection between the electronic element package and second mounting substrate and the first mounting substrate can be enhanced.

According to the present invention, the conductive material that electrically connects the LGA electrode and second substrate electrode with the conductor of an inner wall of the through-hole is successively formed on a surface on an opposite side of a joining surface with the electronic element package and second mounting substrate; therefore, the conductive material on the surface on the opposite side functions as a stopper; and the electrical connection between the LGA electrode and second substrate electrode and the conductor of the through-hole can be maintained (the conductive material can be prevented from slipping, for example) even if a warp is generated in the first mounting substrate or even if any stress by fall is applied.

According to the present invention, the LGA electrode and second substrate electrode can be electrically connected with the conductor of the through-hole even if the amount of the conductive material supplied into each through-hole be uneven.

According to the present invention, even if a plurality of electronic elements be mounted on the second mounting substrate, and a plurality of layers be necessary for electrical interconnection (tracing) in a wiring circuit, the electronic element package and second mounting substrate are arranged so as to form the same plane without piling them, and are electrically interconnected (routed) through the first mounting substrate; and therefore wiring can be formed in the second mounting substrate, and it is unnecessary to make the first mounting substrate thick. Therefore, the electronic device can be made slim.

According to the present invention, impact and stress applied to the electrical connection part between the first mounting substrate and the LGA electrode(s) and second substrate electrode(s) can be relieved, and the connection reliability can be enhanced by joining the electronic element package and the second mounting substrate with resin.

According to the present invention, a layered substrate can be made slim.

### BRIEF DESCRIPTION OF THE DRAWINGS

FIG. 1 is a schematic cross-sectional view of an electronic device according to a first exemplary embodiment of the present invention.

FIG. 2 is a process chart to explain a method of manufacturing an electronic device according to a first exemplary embodiment of the present invention.

FIG. 3 is a schematic cross-sectional view of an electronic device according to a second exemplary embodiment of the present invention.

FIG. 4 is a schematic cross-sectional view of an electronic device according to a third exemplary embodiment of the present invention.

FIG. 5 is a schematic cross-sectional view of an electronic device according to a fourth exemplary embodiment of the present invention.

FIG. 6 is a schematic cross-sectional view of an electronic device according to a fifth exemplary embodiment of the present invention.

FIG. 7 is a schematic cross-sectional view of an electronic device according to a sixth exemplary embodiment of the present invention.

FIG. 8 is a schematic cross-sectional view of an electronic device according to a seventh exemplary embodiment of the present invention.

FIG. 9 is a schematic cross-sectional view of an electronic device according to an eighth exemplary embodiment of the present invention.

FIG. 10 is a schematic cross-sectional view of a layered substrate according to a ninth exemplary embodiment of the present invention.

FIG. 11 is a schematic cross-sectional view of an electronic device according to a tenth exemplary embodiment of the present invention.

FIG. 12 is a schematic plan view of an electronic element package, a second mounting substrate and electronic elements illustrated in FIG. 11.

FIG. 13 is a process chart to explain a method of manufacturing an electronic device according to a tenth exemplary embodiment of the present invention.

FIG. 14 is a schematic cross-sectional view of an electronic device according to an eleventh exemplary embodiment of the present invention.

FIG. 15 is schematic plan views of an electronic element package, a second mounting substrate and electronic elements.

As for explanations of symbols, refer to the end of the specification.

### PREFERRED MODES

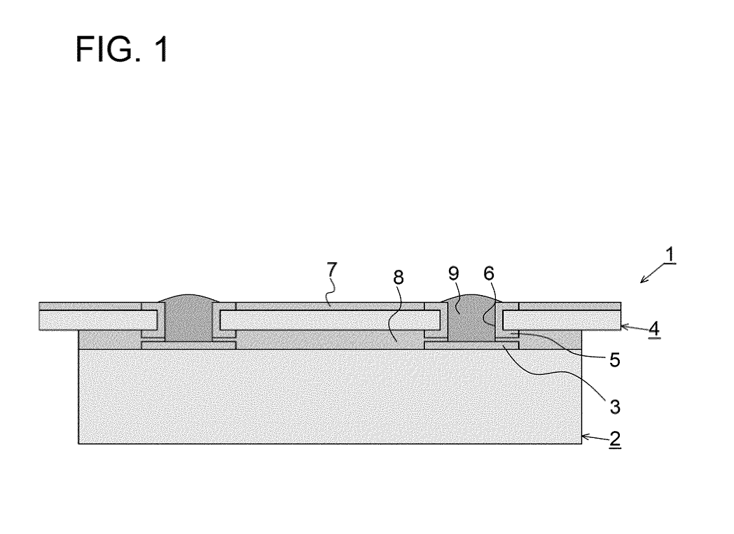

An electronic device according to a first exemplary embodiment of the present invention will be explained. FIG. 1 illustrates a schematic cross-section view of the electronic device according to the first exemplary embodiment of the present invention. The electronic device 1 comprises an electronic element package 2 in which an electronic element is packaged, and a mounting substrate 4 on which the electronic element package 2 is mounted.

The electronic element package 2 is a package of an LGA type having planar LGA electrodes 3. Various electronic elements may be used as the electronic element (not shown) in the electronic element package 2, and, for example, an active element such as a semiconductor chip and a passive element such as a chip capacitor may be applied. An area of a surface, which faces to the mounting substrates 4, of the LGA electrode 3 is equal to or larger than an opening area of a through-hole 6 of the mounting substrate 4.

The mounting substrate 4 has substrate electrodes (lands) 5 formed on the surface of the substrate, and through-holes 6 penetrating the substrate electrode 5 and having a conductor (metal plating (Cu plating, for example) of 5 μm to 30 μm, for example) electrically connecting (successively forming) with the substrate electrode 5 and covering an inner wall. A flexible substrate may be used as the mounting substrate 4. If the LGA electrode 3 of the electronic element package 2 has a diameter of 0.25 mm, for example, the substrate electrode 5 of the mounting substrate 4 preferably has a diameter of 0.15 mm to 0.3 mm. The reason is that a too large substrate electrode 5 causes a short circuit between the adjacent electrodes and that a too small substrate electrode 5 easily causes defects in connection because of dislocation of the position.

In the mounting substrate 4, a region other than the through-hole 6 has no optical transparency to the electronic element package 2. If the mounting substrate 4 has optical transparency like a flexible substrate, for example, in order to give opacity to the mounting substrate 4, an opaque layer 7 to shield light to the electronic element package is provided with at least a transparent part of the mounting substrate 4. In the mode illustrated in FIG. 1, the opaque layer 7 is formed in a region other than the substrate electrode 5 and through-hole and on a surface that does not face to the electronic element package 2. The opaque layer 7 may be formed by applying silver paste on the mounting substrate 4 and, however, a material and forming method is not limited to this, and various materials and forming methods may be selected if the opacity can be given to the mounting substrate 4.

The electronic element package 2 is mounted on the mounting substrate 4 so that the LGA electrode 3 of the electronic element package 2 faces to the substrate electrode 5 of the mounting substrate 4 and, in particular, so that at least a part of the opening of the through-hole 6 overlaps with the LGA electrode 3. The through-hole 6 is filled with a conductive material 9, and the LGA electrode 3 of the electronic element package 2 and the inner wall of the through-hole 6 are electrically and physically connected by the conductive material 9. As the conductive material 9, solder (lead-free solder of a SnAgCu system, for example), conductive adhesive including conductive filler, and the like may be used. In this exemplary embodiment, the conductive material 9 is successively formed extending from the through-hole 6 (LGA electrode 3) to the upper surface of the mounting substrate 4 that is on the back side of the surface facing to the electronic element package 2.

Adhesive 8 is provided between the electronic element package 2 and the mounting substrate 4 except for the opening region of the through-hole 6, and the electronic element package 2 and the mounting substrate 4 is joined by the adhesive 8. In this exemplary embodiment, the LGA electrode 3 is lager than the opening area of the through-hole 6, and the surface of the LGA electrode 3 that does not overlap with the opening of the through-hole 6 is joined to the substrate electrode 5 by the adhesive 8. As the adhesive 8, a photosensitive resin of a positive type may be used, for example. It is preferred that the distance between the LGA electrode 3 of the electronic element package 2 and the substrate electrode 5 of the mounting substrate 4 is 1 μm to 20 μm.

Next, an example of the electronic device 1 according to the first exemplary embodiment will be explained. A flexible substrate having the thickness of 50 μm may be used as the mounting substrate 4, and, an Ag paste having a thickness of 12 μm may cover the flexible substrate as the opaque layer 7. As the electronic element package 2, a semiconductor package in which a semiconductor element is packaged may be used. The LGA electrode 3 of the semiconductor package may have a diameter of 0.25 mm, the substrate electrode 5 of the flexible substrate may have a diameter of 0.25 mm, and the through-hole may have a diameter of 0.15 mm.

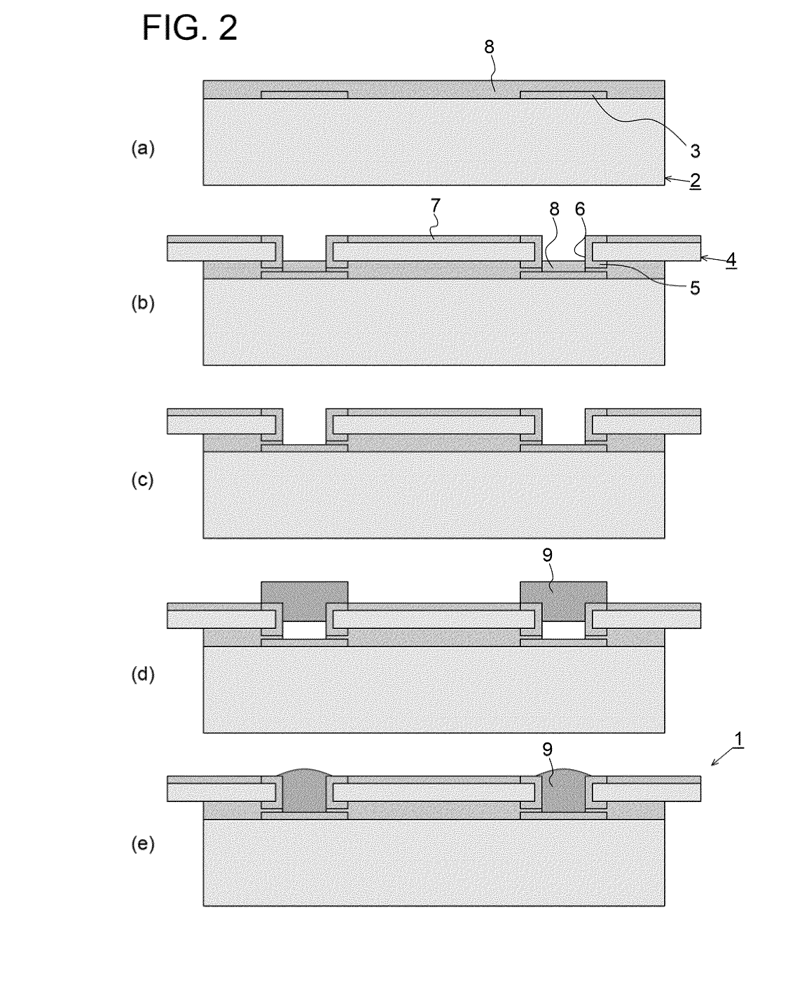

Next, a method of manufacturing the electronic device according to the first exemplary embodiment of the present invention will be explained. FIG. 2 illustrates a process chart to explain the method of manufacturing the electronic device according to the first exemplary embodiment of the present invention. First, the adhesive 8 that is the photosensitive resin of the positive type is provided on the electronic element package 2 of the LGA type (including on the LGA electrode 3) ((a) of FIG. 2; an adhesive providing step). The adhesive 8 preferably has a thickness of 10 μm to 50 μm. The adhesive may be of a liquid form or a film form.

Next, after the mounting substrate 4 and the electronic element package 2 are layered so that at least a part of the opening of the through-hole 6 overlaps with the LGA electrode 3, heat is applied for the adhesion ((b) of FIG. 2; a joining step). In this state, the adhesive 8 exists inside the through-hole 6. A heating condition (time, temperature, and the like) may be suitably set to an optimum condition according to the sort of the adhesive to be used. If a photosensitive resin of the positive type is used, for example, it is heated at 130° C. for 10 minutes. If the area of the LGA electrode 3 is larger than the opening area of the through-hole 6, the region that does not overlap with the opening of the through-hole 6 in the LGA electrode 3 is joined to the mounting substrate 4 (the substrate electrode 5 in FIG. 2) with the adhesive 8.

In the joining step, if the area of the LGA electrode 3 is smaller than the opening area of the through-hole 6 as a third exemplary embodiment described below, the mounting substrate 4 and the electronic element package 2 are layered (stacked) so that at least a part of the LGA electrode 3 is inserted into the through-hole 6.

Next, using an exposure device, the photosensitive resin that is the adhesive 8 inside the through-hole 6 of the mounting substrate 4 is exposed by using the mounting substrate 4 that has the opacity or, if the mounting substrate 4 itself has transparency, the mounting substrate 4 and the opaque layer 7 as a mask (an exposing step). Next, the exposed photosensitive resin in the through-hole 6 is dissolved and removed by a developing solution (a developing step), and the LGA electrode 3 of the electronic element package 2 is exposed ((c) of FIG. 2; an adhesive removing step). An exposure condition (such as an exposure wavelength, exposure energy, and the like) may be suitably set to an optimum condition according to a sort of the photosensitive resin to be used. Ultraviolet rays having a wavelength of 350 nm to 420 nm are applied by 250 J/cm² to 1000 J/cm², for example. The developing solution is not especially limited and may be suitably selected according to the used photosensitive resin.

In this exemplary embodiment, although the photosensitive resin is used as the adhesive, the adhesive and the method of removing the adhesive are not limited to the above mode, and any adhesive and any removing method may be used provided that the adhesive in the through-hole can be removed in the adhesive removing step.

Next, the conductive material 9 is supplied to the through-hole 6 of the mounting substrate 4 ((d) of FIG. 2; a conductive material supplying step). As the method of supplying the conductive material 9, a print method using a metal mask may be selected if a cream solder is used as the conductive material 9, for example. In this case, the thickness of the metal mask is suitably determined according to the opening area (diameter) of the through-hole 6. If through-hole has a diameter of 0.1 mm, for example, the metal mask preferably has a thickness of 0.05 mm.

Next, the conductive material 9 is molten and provided with the inside of the though hole 6, and is moved to the LGA electrode 3 of the electronic element package 2 to electrically and physically connect the LGA electrode 3 of the electronic element package 2 with the conductor of the inner wall of the through-hole 6 by the conductive material 9 ((e) of FIG. 2; an electrical connection step). In the method of melting the conductive material 9, the conductive material 9 may be heated by conveying the mounting substrate 4 on which the electronic element package 2 is mounted through a reflow furnace. By the above process, the electronic device 1 can be manufactured.

According to the electronic device according to the first exemplary embodiment and the manufacturing method thereof, since it is unnecessary to provide the conductive material between the LGA electrode of the electronic element package and the substrate electrode, the distance between the electronic element package and the mounting substrate can be reduced (10 μm, for example), and therefore the electronic device can be made slim. The electronic device can be further made thinner by reducing the area of the LGA electrode relative to the opening area of the through-hole, not forming the substrate electrode (land) of the mounting substrate and the like.

Since the heat treating for the electrical connection by the conductive material is performed after the electronic element package and the mounting substrate are joined with the adhesive, the generation of warp of the mounting substrate can be restricted in the heat treatment. Therefore, the reliability of the electrical connection between the electronic element package and the mounting substrate can be enhanced.

As illustrated in (e) of FIG. 2, the conductive material that electrically connects the LGA electrode with the conductor on the inner wall of the through-hole is successively formed on the surface which is on the opposite side of the surface to be joined with the electronic element package; therefore, the conductive material on the surface on the opposite side functions as a stopper; and the electrical connection between the LGA electrode and the conductor of the through-hole can be maintained (the conductive material is prevented from falling-down, for example) even if the warp of the mounting substrate occurs or stress be applied by fall.

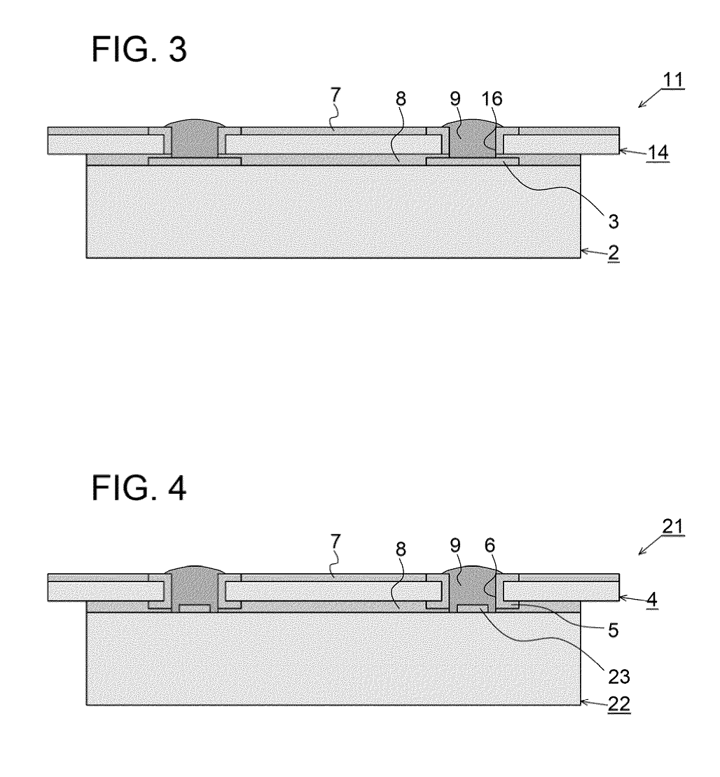

Next, an electronic device according to a second exemplary embodiment of the present invention will be explained. FIG. 3 illustrates a schematic cross-section view of the electronic device according to the second exemplary embodiment of the present invention. In the first exemplary embodiment, the mounting substrate 4 has the substrate electrode 5 (land) that is formed around the opening of the through-hole 6 and successively provided with the conductor of the through-hole 6 on the surface of the mounting substrate opposite to the electronic element package 2, whereas, in the second exemplary embodiment, a mounting substrate 14 does not have a conductor corresponding to the substrate electrode 5 of the first exemplary embodiment.

An electronic device 11 according to the second embodiment has the electronic element package 2 and the mounting substrate 14 on which the electronic element package 2 is mounted. Since a substrate electrode is not formed on the surface of the mounting substrate 14 facing to the electronic element package 2, the LGA electrode 3 of the electronic element package 2 is joined to a substrate (resin) of the mounting substrate 14 with the adhesive 8 except the through-hole (opening and conductor) 16. Since the LGA electrode 3 and the conductor of the through-hole 16 are electrically connected by the conductive material 9 through the opening of the through-hole 16 (that is, the conductor of the through-hole 16 actually serves as an electrode), the electrical connection between the electronic element package 2 and the mounting substrate 14 can be maintained even if a land be not formed on a surface of the mounting substrate 14.

The other modes may be same as the electronic device according to the first exemplary embodiment.

With regard to a method of not forming a substrate electrode on the surface of the mounting substrate 14, an appropriate method may be suitably selected. For example, when a wiring layer of the mounting substrate 14 is etched, the wiring layer around the opening of through-hole 16 (substrate electrode) may be removed by the etching or after the mounting substrate 14 is formed, a part corresponding to a substrate electrode may be mechanically removed (grinding removal, for example).

According to the electronic device according to the second exemplary embodiment, since a substrate electrode is not formed on the surface of the mounting substrate facing to the electronic element package, the electronic device can be made thinner by the thickness corresponding to the substrate electrode.

Next, an electronic device according to a third exemplary embodiment of the present invention will be explained. FIG. 4 illustrates a schematic cross-section view of the electronic device according to the third exemplary embodiment of the present invention. In the first exemplary embodiment, the LGA electrode 3 of the electronic element package 2 has a surface area larger than the opening area of the through-hole 6 of the mounting substrate 4, whereas, in the third exemplary embodiment, an LGA electrode 23 of an electronic element package 22 has an surface area smaller than the opening area of through-hole 6 of the mounting substrate 4.

An electronic device 21 according to the third exemplary embodiment has the electronic element package 22 and the mounting substrate 4 on which the electronic element package 22 is mounted. The LGA electrode 23 of the electronic element package 22 is included within the opening of the through-hole 6, and the upper surface of the LGA electrode 23 facing to the electronic element package 22 is located inside the through-hole 6. With this, the upper surface and side surface of the LGA electrode 23 are covered with the conductive material 9 and electrically connected with the conductor of the through-hole 6.

The substrate electrode 5 of the mounting substrate 4 faces to a region, other than the LGA electrode 23, of the electronic element package 22 and is joined with the adhesive 8.

The other modes may be same as the electronic device according to the first exemplary embodiment.

An example of the electronic device 21 according to a third exemplary embodiment is explained. For example, if the substrate electrode 5 of the mounting substrate 4 has a diameter of 0.25 mm and the opening of the through-hole 6 has a diameter of 0.15 mm, the LGA electrode 23 of the electronic element package 22 may have a diameter of 0.1 mm.

According to the electronic device according to the third exemplary embodiment, the electronic device can be further made thinner by the thickness as thick as the LGA electrode of the electronic element package is inserted into the through-hole. Since the LGA electrode is covered with the conductive material, reliability to heat stress can be enhanced.

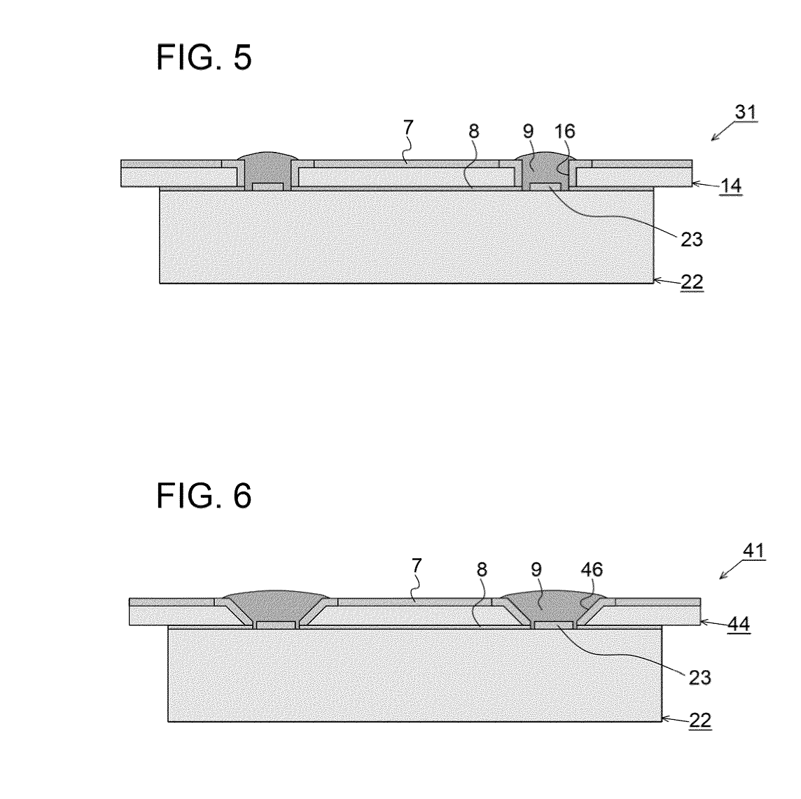

Next, an electronic device according to a fourth exemplary embodiment of the present invention will be explained. FIG. 5 illustrates a schematic cross-section view of the electronic device according to the fourth exemplary embodiment of the present invention. The fourth exemplary embodiment has a mode of combination of the second exemplary embodiment and the third exemplary embodiment.

An electronic device 31 according to the fourth exemplary embodiment has the electronic element package 22 and the mounting substrate 14 on which the electronic element package 22 is mounted. The area of the surface, which faces to the mounting substrate 14, of the LGA electrode 23 of the electronic element package 22 is smaller than the opening area of the through-hole 16 as same as the third exemplary embodiment, and a upper part of the LGA electrode 23 is inserted into the through-hole 16. The LGA electrode 23 is covered with the conductive material 9 and electrically connected with the conductor on the through-hole 16.

The mounting substrate 14 does not have a conductor corresponding to a substrate electrode on a surface facing to the electronic element package 22 as same as the second exemplary embodiment, and a region of the mounting substrate 14 other than the opening of the through-hole 16 is joined with a region of the electronic element package 22 other than the LGA electrode 23 by the adhesive 8.

The other modes may be same as the electronic device according to the first exemplary embodiment.

According to the electronic device according to fourth exemplary embodiment, the electronic device can be further made thinner by the thickness as thick as the LGA electrode is inserted into the through-hole and as the thickness of the substrate electrode on the surface of the mounting substrate.

Next, an electronic device according to a fifth exemplary embodiment of the present invention will be explained. FIG. 6 illustrates a schematic cross-section view of the electronic device according to the fifth exemplary embodiment of the present invention. In the fifth exemplary embodiment, a through-hole 46 of a mounting substrate 44 is formed in a taper shape.

An electronic device 41 according to the fifth embodiment has an electronic element package 22 and the mounting substrate 44 on which the electronic element package 22 is mounted. The through-hole 46 of the mounting substrate 44 has a shape of a truncated cone such that a diameter is reduced toward the electronic element package 22.

An example of the electronic device 41 according to the fifth exemplary embodiment will be explained. In the through-hole 46, for example, an opening facing to the electronic element package 22 may have a diameter of 0.15 mm, and an opening on the opposite surface (on a conductive material 9 supplying side) may have a diameter of 0.2 mm.

According to the electronic device of the fifth exemplary embodiment, since the opening on the conductive material supplying side of the through-hole has a larger diameter, an efficiency of supplying the conductive material to the inside of the through-hole can be enhanced.

Although FIG. 6 illustrates the electronic element package according to the third exemplary embodiment, it is naturally noted that the electronic element package according the first exemplary embodiment may be applied. Although FIG. 6 also illustrates the mounting substrate having the substrate electrode on the surface of the mounting substrate, it is naturally noted that the mounting substrate not having the substrate electrode (land) on the surface of the mounting substrate, as the second exemplary embodiment, may be applied. In the fifth exemplary embodiment, the other modes may be same as the electronic device according to the first exemplary embodiment.

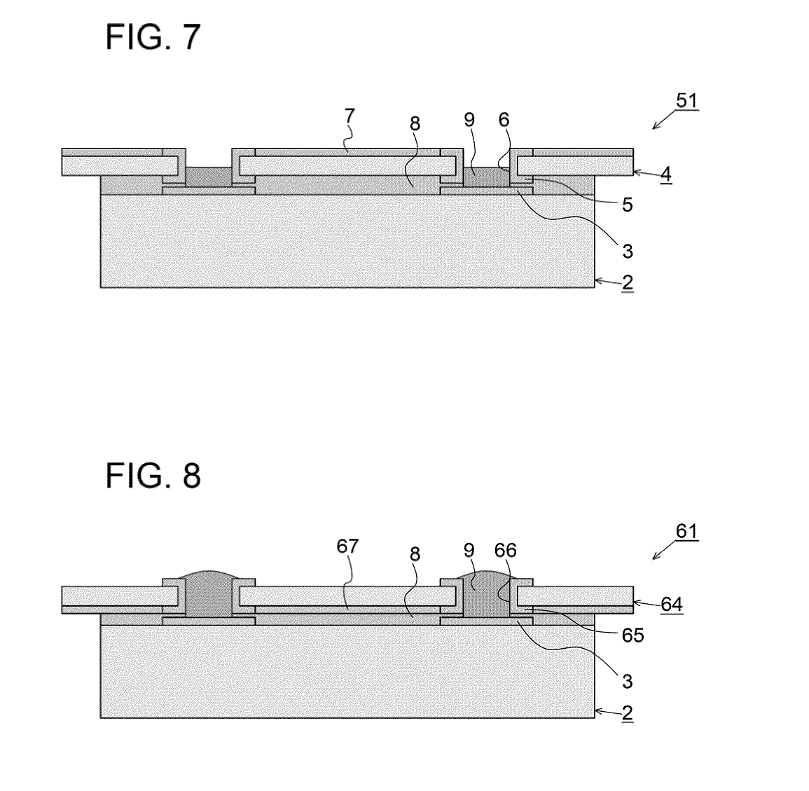

Next, an electronic device according to a sixth exemplary embodiment of the present invention will be explained. FIG. 7 illustrates a schematic cross-section view of the electronic device according to the sixth exemplary embodiment of the present invention. In the first exemplary embodiment to the fifth exemplary embodiment illustrated in FIGS. 1-6, the conductive material 9 is provided in the entirety of the through-holes 6, 16, 46, whereas the conductive material 9 may be provided in only a part of the through-hole 6 in the sixth exemplary embodiment as illustrated in FIG. 7 if the LGA electrode 3 of the electronic element package 2 and the conductor of the through-hole 6 can be electrically connected.

Accordingly, in one electronic device according to the first exemplary embodiment to the fifth exemplary embodiment, the through-hole in which the conductive material is fully provided as illustrated in FIGS. 1-6 and the through-hole in which the conductive material is partially provided as illustrated FIG. 7 may coexist in one mounting substrate. That is, in a plurality of the through-holes in one electronic device, the amount of the conductive material may be unequal (not uniform). For example, in case where the conductive material of a paste form is supplied by a printing manner, the amount of the printing may be unequal as far as the LGA electrode and the conductor of the through-hole can be electrically connected.

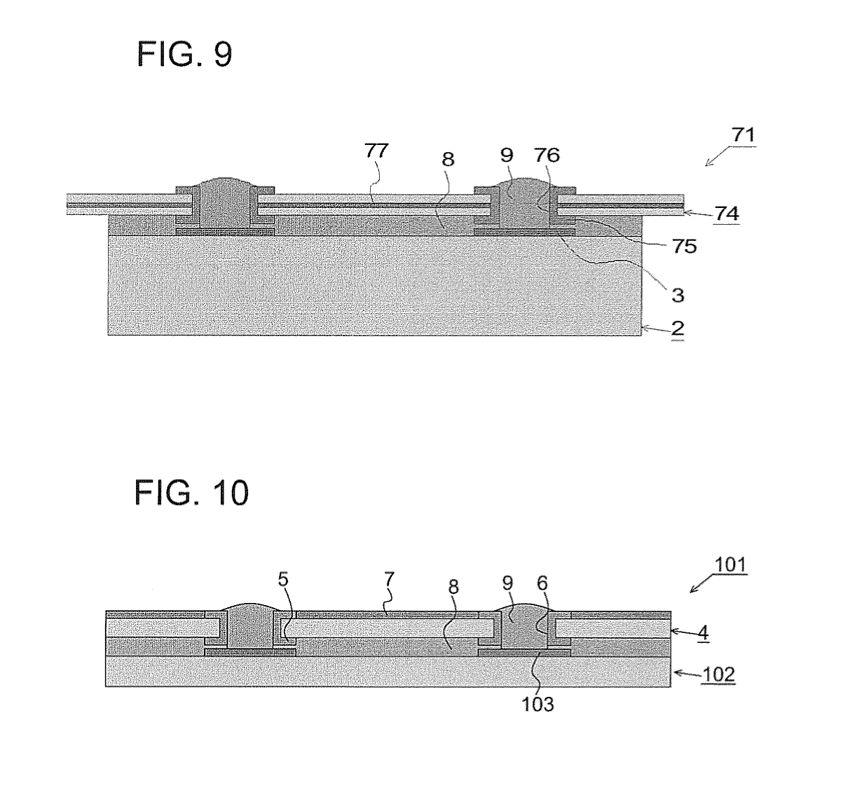

Next, electronic devices according to a seventh exemplary embodiment and eighth exemplary embodiment of the present invention will be explained. FIG. 8 illustrates a schematic cross-section view of the electronic device according to the seventh exemplary embodiment of the present invention, and FIG. 9 illustrates a schematic cross-section view of the electronic device according to the eighth exemplary embodiment of the present invention. In the first exemplary embodiment to the sixth exemplary embodiment, the opaque layer 7 which is provided if the mounting substrate has the transparency is formed on the surface of the mounting substrate on the back side of the surface facing to the electronic element package, whereas in the seventh exemplary embodiment and eighth exemplary embodiment, the opaque layer is formed in the other positions.

In an electronic device 61 according to the seventh exemplary embodiment illustrated in FIG. 8, an opaque layer 67 is formed on a surface facing to the electronic element package 2 in the mounting substrate 64 and joined to the electronic element package 2 by the adhesive 8.

In an electronic device 71 according to the eighth exemplary embodiment illustrated in FIG. 9, an opaque layer 77 is formed within the mounting substrate 74.

The opaque layer may be formed in any part of the mounting substrate as illustrated in FIGS. 1-9 if the mounting substrate has the transparency. If the mounting substrate partially has the transparency, the opaque layer may be formed only in the part having the transparency.

The seventh exemplary embodiment and eighth exemplary embodiment illustrated in FIGS. 8 and 9 are explained based on the first exemplary embodiment illustrated in FIG. 1 and, however, may be applied to the second exemplary embodiment to the sixth exemplary embodiment.

Next, a layered substrate according to a ninth exemplary embodiment of the present invention will be explained. FIG. 10 illustrates a schematic cross-section view of a laminate of layered mounting substrate according to the ninth exemplary embodiment of the present invention. Although, in the first exemplary embodiment to eighth exemplary embodiment, the electrical connections between the electronic element package and the mounting substrate are explained, the above modes may be also applied to layered (laminated) mounting between the mounting substrates.

A laminate of mounting substrates (may be termed as “layered substrates”) 101 comprises a first mounting substrate 4 and a second mounting substrate 102. A mode of the first mounting substrate 4 may be the same as the mode of the mounting substrate 4 in the first exemplary embodiment. The second mounting substrate 102 has second substrate electrodes 103 which are planar electrodes to be electrically connected with the conductor (the through-hole 6) of the first mounting substrate 4.

The connection mode between the first mounting substrate 4 and the second mounting substrate 102 in the layered substrates 101 and the manufacturing method are the same as the connection mode between the mounting substrate 4 and the electronic element package 2 and the manufacturing method according to the first exemplary embodiment apart from replacing the electronic element package with the second mounting substrate; an explanation herein is omitted by reference to the explanation of the first exemplary embodiment. Therefore, the layered substrates 101 can be made thin.

Although the layered substrates according to the ninth exemplary embodiment illustrated in FIG. 10 are explained based on the first exemplary embodiment, the connection modes, the modes of the mounting substrate and the like according to the second exemplary embodiment to the eighth exemplary embodiment may be applied to the layered substrates according to the ninth exemplary embodiment.

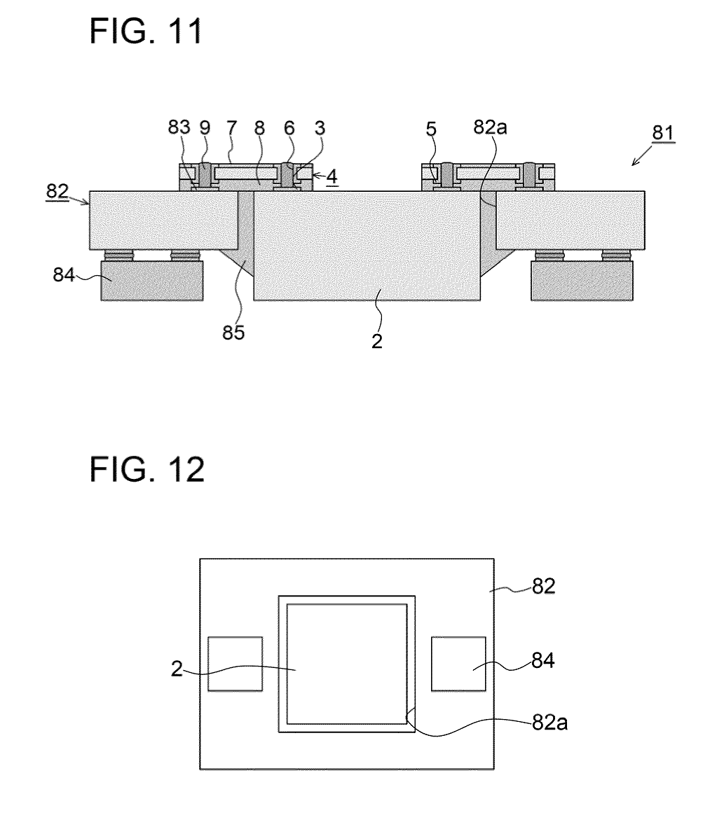

Next, an electronic device according to a tenth exemplary embodiment of the present invention will be explained. FIG. 11 illustrates a schematic cross-section view of the electronic device according to the tenth exemplary embodiment of the present invention. In an electronic device 81 according to the tenth exemplary embodiment, the first mounting substrate is connected with the electronic element package and the second mounting substrate. The electronic device 81 has the electronic element package 2, first mounting substrates 4, and a second mounting substrate 82. Each mode of the electronic element package 2 and the first mounting substrate 4 is the same as each mode of the electronic element package 2 and the mounting substrate 4 according to the first exemplary embodiment.

The second mounting substrate 82 has a second substrate electrode 83 of a planar type to be electrically connected with the first substrate electrode 5 of the first mounting substrate 4. At least one electronic element 84 is mounted on the second mounting substrate 82. In the mode illustrated in FIG. 11, the electronic devices 84 are mounted on the surface on the opposite side of the surface on which the first substrate electrodes are formed.

One first mounting substrate 4 is electrically connected with the electronic element package 2 and the second mounting substrate 82 so as to build a bridge. If the first substrate electrodes 5 of the first mounting substrates 4 which are electrically connected with the LGA electrodes 3 of the electronic element package 2 and the second substrate electrode 83 of the second mounting substrate 82 lie in the same plane, the electronic element package 2 and the second mounting substrate 82 are disposed so that the LGA electrode 3 of the electronic element package 2 and the second substrate electrode 83 of the second mounting substrate 82 lie in the same plane. It is preferred that the electronic element package 2 and the second mounting substrate 82 are joined (fixed) with a resin 85. As the resin 85, a resin of an epoxy type may be used, for example.

The mode of the electrical connection between the first mounting substrate 4 and the electronic element package 2 and second mounting substrate 82 is the same as the first exemplary embodiment apart from that the first mounting substrate 4 electrically connects the both.

FIG. 12 illustrates a schematic plan view of the electronic element package 2, the second mounting substrate 82 and the electronic elements 84 illustrated in FIG. 11. In FIG. 12, illustration of mounting substrate 4, resin 85 and the like are omitted. In the tenth exemplary embodiment, a penetrating opening 82a to insert and dispose the electronic element package 2 is formed in the second mounting substrate 82. If the outer profile of the electronic element package is a rectangle of 12 mm×12 mm, the shape and size of the penetrating opening 82a may have the shape larger than it, for example, a rectangle of 14 mm×14 mm. The electronic element package 2 is inserted into the penetrating opening 82a and the resin 85 is provided in at least a gap between the electronic element package 2 and the second mounting substrate 82. The resin 85 is preferably provided so as to form a plane flush with the electronic element package 2 and the second mounting substrate 82 against the first mounting substrate 4.

In the tenth exemplary embodiment, although the electronic element package 2 is provided in the penetrating opening 82a of the second mounting substrate 82, an electronic element 84 may be provided in place of the electronic element package 2. For example, providing thicker one of the electronic element package 2 and electronic element 84 in the penetrating opening 82a is preferable for contribution of thinning.

Although the tenth exemplary embodiment is explained using the mounting substrate and the electronic element package according to the first exemplary embodiment, the mounting substrates and the electronic element packages according to the second exemplary embodiment to the eighth exemplary embodiment may be also applied to the tenth exemplary embodiment. Any combination in the exemplary embodiments may be applied to the tenth exemplary embodiment.

According to the electronic device according to the tenth exemplary embodiment, since the second mounting substrate and the electronic element package are electrically connected through the first mounting substrate, even if a plurality of electronic elements are mounted on the second mounting substrate, and a plurality of layers are necessary for forming a wiring (tracing) circuit, the second mounting substrate can be used for wiring without making the first mounting substrate thick, and therefore the electronic device can be made thin. The electronic device can be further made thinner by inserting the electronic element package or electronic element into the penetrating opening of the second mounting substrate.

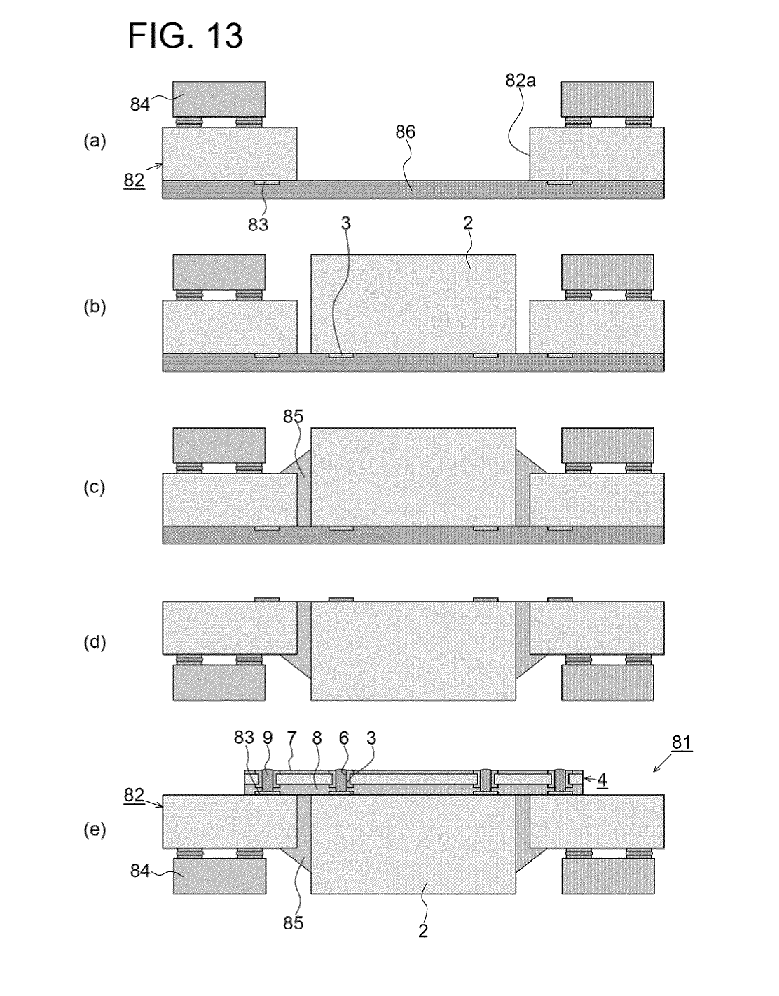

Next, a method of manufacturing the electronic device according to the tenth exemplary embodiment of the present invention will be explained. FIG. 13 illustrates a process chart to explain the method of manufacturing the electronic device according to the tenth exemplary embodiment of the present invention.

First, the second mounting substrate 82 on which at least one electronic element 84 is mounted is glued on an adhesive plate 86 so that the second substrate electrode 83 faces the adhesive plate 86 (FIG. 13; a position determining step). As the adhesive plate 86, for example, a laminate of Keiju® sheet and aluminum plate may be used. The second mounting substrate 82 and the electronic element package 2 glued on the adhesive plate 86 can be easily removed.

Next, the electronic element package 2 is glued on the adhesive plate 86 so that the LGA electrodes face the adhesive plate 86 ((b) of FIG. 13; the position determining step). It is preferred that a mark to indicate a position for disposing the electronic element package 2 and the like is formed on the second mounting substrate 82 or adhesive plate 86. After the electronic element package 2 is glued on the adhesive plate 86, the second mounting substrate 82 may be glued.

Next, resin 85 is supplied between the electronic element package 2 and the second mounting substrate 82 which are glued on the adhesive plate 86, and is hardened by heating to join the electronic element package 2 and the second mounting substrate 82 ((c) of FIG. 13; a joining step). As a method of supplying the resin 85, a potting method may be used, and in an electronic device according to an eleventh exemplary embodiment explained below, the whole surface on the electronic element package and second mounting substrate may be sealed with resin by a transfer molding method.

Next, the electronic element package 2 and second mounting substrate 82 that are joined by the resin 85 are removed from the adhesive plate 86 ((d) of FIG. 13; a removing step). The LGA electrodes 3 of the electronic element package 2 and the second substrate electrodes 83 of the second mounting substrate 82 can lie on the same plane or on almost same plane and face to the same direction by removing the electronic element package 2 and second mounting substrate 82 from the adhesive plate 86.

Next, the first mounting substrate 4 is electrically connected with the electronic element package 2 and second mounting substrate 82 by the method similar to the method of manufacturing the electronic device according to the first exemplary embodiment ((e) of FIG. 13). The mounting substrate 4 may extend across the electronic element package 2 as illustrated in (e) of FIG. 13.

According to the method of manufacturing the electronic device according to the tenth exemplary embodiment, by using the adhesive plate, a structure which can mount the first mounting substrate on the electronic element package and second mounting substrate in the same time can be easily formed. By the first mounting substrate, the electronic element package and second mounting substrate can be electrically connected easily.

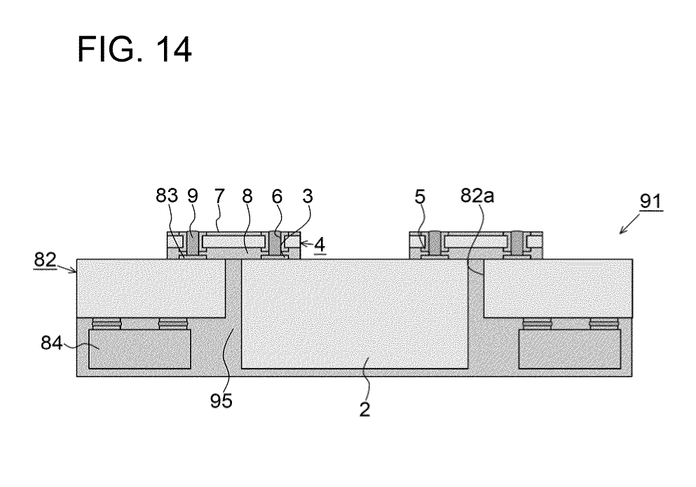

Next, an electronic device according to an eleventh exemplary embodiment of the present invention will be explained. FIG. 14 illustrates a schematic cross-section view of the electronic device according to the eleventh exemplary embodiment of the present invention. In the tenth exemplary embodiment, the resin mainly joins only between the electronic element package and the second mounting substrate, whereas, in an electronic device 91 according to the eleventh exemplary embodiment, resin 95 covers the entirety of one side of the electronic element package 2 and second mounting substrate 82 so as to seal the electronic elements 84 and the electronic element package 2.

According to the electronic device according to the eleventh exemplary embodiment, since the surface on the back side of the surface on which the first mounting substrate 4 is mounted can be made flat, a step of connecting the mounting substrate 4 (the conductive material supplying step, for example) can be easily performed. Therefore, for example, the thickness of the adhesive can be made even, and variation in the amount of the supplied conductive material can be reduced.

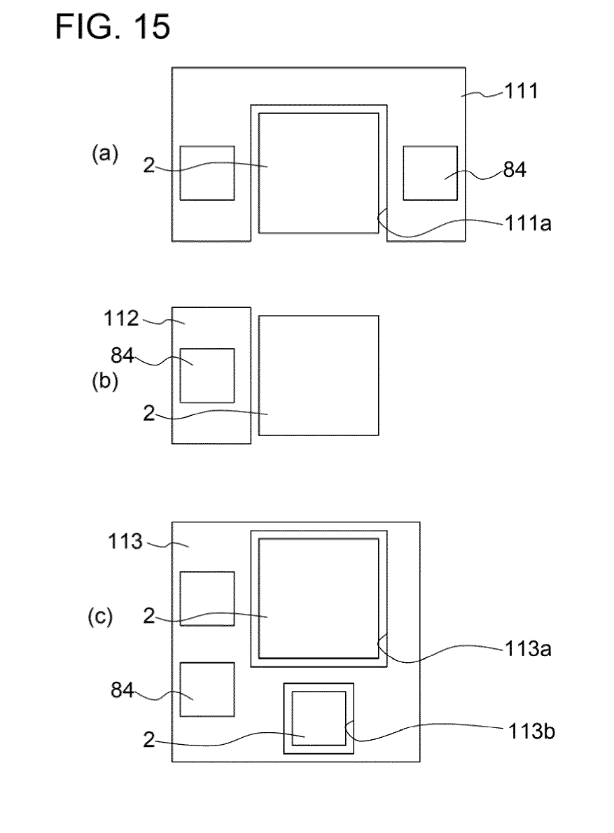

Other mode of the second mounting substrate in the tenth exemplary embodiment and eleventh exemplary embodiment will be explained. In the mode illustrated in FIG. 12, although the penetrating opening 82a is formed to dispose the electronic element package 2 in the center of the second mounting substrate 82, the shape of the second mounting substrate can be suitably modified according to the positions of the electronic element package and electronic element. For example, as illustrated in (a) of FIG. 15, if the electronic element package 2 is disposed around the end of the second mounting substrate 111, a notch 111a can be formed in the end of the second mounting substrate 111. If the electronic element package 2 is disposed or a space for disposing the electronic element is unnecessary, as illustrated in (b) of FIG. 15, the electronic element package 2 may be merely disposed on the side of a second mounting substrate 112 without providing the penetrating opening or notch in the second mounting substrate 112. If a plurality of the electronic element packages 2 are disposed, as illustrated in (c) of FIG. 15, a plurality of notches or penetrating openings 113a, 113b may be formed in a second mounting substrate 113.

In FIGS. 1-15, illustration of elements, which are not used in the explanation, such as wiring layer, the through-hole and the like is omitted.

An electronic device of the present invention and a manufacturing method thereof have been described based on the abovementioned exemplary embodiments, but there is no limitation to the abovementioned exemplary embodiments, and clearly various changes, modifications, improvements, and the like within the scope of the invention are included. Furthermore, various combinations, substitutions and selections of disclosed elements are possible within the scope of the present invention.

Further problems, objects and expanded modes of the present invention are clear from the entire disclosed matter of the present invention including the claims.

### EXPLANATIONS OF SYMBOLS

1, 11, 21, 31, 41, 51, 61, 71, 81, 91 electronic device
2, 22 electronic element package
3, 23 LGA electrode
4, 14, 44, 64, 74 (first) mounting substrate
5, 15, 45, 65, 75 (first) substrate electrode
6, 16, 46, 66, 76 through-hole
7, 67, 77 opaque layer
8 adhesive
9 conductive material
82, 102, 111, 112, 113 second mounting substrate
82a, 113a, 113b penetrating opening
111a notch
83, 103 second substrate electrode
84 electronic element
85, 95 resin
86 adhesion plate
101 layered substrate

What is claimed is:

1. An electronic device comprising:
an electronic element package; and
a first mounting substrate on which said electronic element package is mounted; wherein
said electronic element package has an LGA electrode of a Land Grid Array type;
said first mounting substrate has a through-hole having a conductor which covers an inner wall;
said electronic element package is mounted on said first mounting substrate so that at least a part of an opening of said through-hole overlaps with said LGA electrode;
said LGA electrode and said conductor of said through-hole are electrically connected by a conductive material provided inside said through-hole; and
in said LGA electrode, at least a part of a region that does not overlap with said opening of said through-hole is joined with said first mounting substrate by an adhesive.

2. The electronic device according to claim 1, further comprising a second mounting substrate having a substrate electrode electrically connected with said conductor of said through-hole; wherein
said first mounting substrate is mounted on said second mounting substrate so that at least a part of said opening of said through-hole overlaps with said substrate electrode;
said substrate electrode and said conductor of said through-hole are electrically connected by a conductive material provided inside said through-hole; and
in said substrate electrode, at least a part of a region that does not overlap with said opening of said through-hole is joined with said first mounting substrate by an adhesive.

3. The electronic device according to claim 1, wherein
an area of said LGA electrode or an area of said LGA electrode and said substrate electrode is larger than an opening area of said through-hole on a side facing to said LGA or said LGA and said substrate electrode.

4. An electronic device comprising:
an electronic element package; and
a first mounting substrate on which said electronic element package is mounted; wherein
said electronic element package has an LGA electrode of a Land Grid Array type;
said first mounting substrate has a through-hole having a conductor which covers an inner wall;
said LGA electrode has an area smaller than an opening area of said through-hole on a side facing to said LGA electrode;
said electronic element package is mounted on said first mounting substrate so that said LGA electrode is included in an opening of said through-hole;
said LGA electrode and said conductor of said through-hole are electrically connected by a conductive material provided inside said through-hole;
an upper surface of said LGA electrode facing to said first mounting substrate is located inside said through-hole; and
an adhesive is provided, on an area in which said electronic element package faces said first mounting substrate, in a region other than a region of said opening of said through-hole.

5. The electronic device according to claim 4, further comprising
a second mounting substrate having a substrate electrode electrically connected in said conductor of said through-hole; wherein
said substrate electrode has an area smaller than an opening area of said through-hole on a side facing said substrate electrode;
said first mounting substrate is mounted on said second mounting substrate so that said substrate electrode is included in an opening of said through-hole;
said substrate electrode and said conductor of said through-hole are electrically connected by said conductive material provided inside said through-hole;
an upper surface of said substrate electrode facing to said first mounting substrate is located inside said through-hole; and
in an area in which said first mounting substrate faces said second mounting substrate, an adhesive is provided in a region other than a region of said opening of said through-hole.

6. The electronic device according to claim 2, wherein
said LGA electrode of said electronic element package is provided on a same plane with said substrate electrode of said second mounting substrate.

7. The electronic device according to claim 2, wherein
said second mounting substrate has a penetrating opening or notch; and
said electronic element package is disposed in said penetrating opening or notch.

8. The electronic device according to claim 2, wherein
said electronic element package is joined to said second mounting substrate with a resin.

9. The electronic device according to claim 2, wherein
at least one electronic element is mounted on said second mounting substrate.

10. The electronic device according to claim 4, wherein
said LGA electrode or said LGA electrode and said substrate electrode is/are covered with said conductive material.

11. The electronic device according to claim 1, wherein
said first mounting substrate has a conductor that faces said LGA electrode or said LGA electrode and said substrate electrode, said conductor being successively formed with said conductor of said through-hole on a surface of said first mounting substrate facing to said electronic element package or said electronic element package and second mounting substrate; and
at least a part of a region that does not overlap with said opening of said through-hole in said LGA electrode or said LGA electrode and said substrate electrode is joined to said conductor on said surface of said first mounting substrate by an adhesive.

12. The electronic device according to claim 1, wherein
said first mounting substrate does not have a conductor that faces said LGA electrode or said LGA electrode and said substrate electrode; said conductor being successively formed with a conductor of said through-hole on a surface of said first mounting substrate facing to said electronic element package or said electronic element package and second mounting substrate.

13. The electronic device according to claim 1, wherein
in an area in which said first mounting substrate faces said electronic element package or said electronic element package and said second mounting substrate, an adhesive is provided on a region other than a region of said opening of said through-hole.

14. The electronic device according to claim 1, wherein
said adhesive is photosensitive resin.

15. The electronic device according to claim 1, wherein
in a region other than said through-hole, said first mounting substrate does not have optical transparency with respect to said electronic element package or said electronic element package and second mounting substrate.

16. The electronic device according to claim 15, wherein
said first mounting substrate has an opaque layer that shields light incident to said electronic element package or said electronic element package and said second mounting substrate in at least one part.

17. The electronic device according to claim 1, wherein
said conductive material is successively formed extending from said through-hole to a surface of said first mounting substrate on an opposite side of a surface of said first mounting substrate facing to said electronic element package or said electronic element package and said second mounting substrate.

18. A layered substrate comprising:
a first mounting substrate; and
a second mounting substrate that is layered and mounted on said first mounting substrate; wherein
said second mounting substrate has a planar electrode;
said first mounting substrate has a through-hole having a conductor that covers an inner wall;
said first mounting substrate is mounted on a second mounting substrate so that at least a part of an opening of said through-hole overlaps with said planar electrode;
said planar electrode and said conductor of said through-hole are electrically connected by a conductive material provided inside said through-hole; and
in said planar electrode, at least a part of a region that does not overlap with said opening of said through-hole is joined to said first mounting substrate with an adhesive.

19. A layered substrate comprising:
a first mounting substrate; and
a second mounting substrate that is layered and mounted on said first mounting substrate; wherein
said second mounting substrate has a planar electrode;
said first mounting substrate has a through-hole having a conductor that covers an inner wall;
said planar electrode has an area smaller than an opening area of said through-hole on a side facing said planar electrode;
said first mounting substrate is mounted on said second mounting substrate so that said planar electrode is included in said opening of said through-hole;
said planar electrode and said conductor of said through-hole are electrically connected by a conductive material provided inside said through-hole;
an upper surface of said planar electrode facing to said first mounting substrate is located inside said through-hole; and
in an area in which said first mounting substrate faces said second mounting substrate, an adhesive is provided in a region other than a region of said opening of said through-hole.

20. The layered substrate according to claim 18, wherein
said adhesive is a photosensitive resin; and
in a region other than said through-hole, said first mounting substrate does not have optical transparency with respect to said second mounting substrate.

21. A method of manufacturing an electronic device in which an electronic element package is mounted on a first mounting substrate, comprising:
applying an adhesive on at least a part of a surface of said electronic element package in which an LGA electrode of a Land Grid Array type is formed;
layering said electronic element package on said first mounting substrate having a through-hole that has a conductor on an inner wall so that at least a part of an opening of said through-hole overlaps with said LGA electrode;
removing said adhesive in said through-hole so as to expose at least a part of said LGA electrode from said opening of said through-hole;
supplying a conductive material to said through-hole from an opening on the opposite side of the opening of said through-hole facing said LGA electrode; and
moving said conductive material to the exposed surface of said LGA electrode, and electrically connecting said LGA electrode with said conductor of said through-hole by said conductive material.

22. A method of manufacturing an electronic device comprising:
determining positions by gluing an electronic element package having an LGA electrode of a Land Grid Array type and a second mounting substrate on which at least one electronic element is mounted and has a planar electrode on an adhesive plate so that said LGA electrode and said planar electrode face said adhesive plate;
joining said electronic element package and said second mounting substrate with a resin;
removing said electronic element package and said second mounting substrate from said adhesive plate;
providing an adhesive on at least a part of a surface of said electronic element package on which said LGA electrode is formed and of a surface of said second mounting substrate on which said planar electrode is formed;
layering a first mounting substrate that has at least one through-hole having a conductor on an inner wall on said electronic element package and said second mounting substrate so that at least a part of an opening of said through-hole overlaps with said LGA electrode and said planar electrode;
removing the adhesive in said through-hole so that at least a part of said LGA electrode and said planar electrode is exposed from said opening of said through-hole;
supplying a conductive material to said through-hole from an opening on an opposite side of the opening of said through-hole facing said LGA electrode and said planar electrode; and
moving said conductive material to the exposed surface of said LGA electrode and said planar electrode; and to electrically connecting said LGA electrode and said planar electrode with said conductor of said through-hole by said conductive material.

23. The method according to claim 21, wherein
said LGA electrode or said LGA electrode and planar electrode has/have an area(s) larger than an opening area of said through-hole on a side facing said LGA electrode or said LGA electrode and planar electrode; and
at least a part of a region that does not overlap with said opening of said through-hole in said LGA electrode or said LGA electrode and planar electrode is joined to said first mounting substrate by said adhesive.

24. The method according to claim 21, wherein
said LGA electrode or said LGA electrode and planar electrode has/have an area(s) smaller than an opening area of said through-hole on a side facing said LGA electrode or said LGA electrode and planar electrode; and
at least a part of said LGA electrode or of said LGA electrode and planar electrode, facing said first mounting substrate, is inserted into said through-hole.

25. The method according to claim 21, wherein
said adhesive is a photosensitive resin; and
the method comprises exposing said adhesive in said through-hole, and removing said adhesive in said through-hole by a developing solution after the exposing said adhesive.

26. The method according to claim 25, wherein
in a region other than said through-hole, said first mounting substrate has opacity with respect to said electronic element package or said electronic element package and said second mounting substrate; and
only said adhesive in said through-hole is exposed from the opening of said through-hole using said first mounting substrate as a mask.

27. The method according to claim 21, wherein
said conductive material is cream solder; and
in the electrical connecting step, said LGA electrode or said LGA electrode and planar electrode is/are electrically connected to said conductor of said through-hole by heating and melting said conductive material.

28. A method of manufacturing a layered substrate comprising:
providing an adhesive at least on a part of a second mounting substrate in which a planar electrode is formed;
layering a fist mounting substrate that has a through-hole having a conductor on an inner wall on said second mounting substrate so that at least a part of an opening of said through-hole overlaps with said planar electrode;
removing said adhesive in said through-hole so that at least a part of said planar electrode is exposed from said opening of said through-hole;
supplying a conductive material to said through-hole from an opening on an opposite side of the opening of said through-hole facing said planar electrode; and
moving said conductive material to the exposed surface of said planar electrode; to electrically connecting said planar electrode to said conductor of said through-hole by said conductive material.
